(19) United States
(12) Patent Application Publication
(10) Pub. No.: US 2012/0037233 A1
(43) Pub. Date: Feb. 16, 2012

(54) DIRECT FREE COOLING

(76) Inventor: Renee Seeliger, Pinneberg (DE)

(21) Appl. No.: 13/265,625

(22) PCT Filed: Apr. 26, 2010
(86) PCT No.: PCT/EP10/02552

§ 371 Date: Oct. 21, 2011

(30) Foreign Application Priority Data
Apr. 27, 2009 (EP) 09005824.9

(51) Int. Cl. F16K 31/64

(52) U.S. Cl. 137/1; 137/527; 137/544

(57) ABSTRACT

The invention relates to a mixing box for regulating temperature, having a base body through which at least one air stream can be conducted and in which there is arranged at least one filter device, through which the air stream can be conducted. The air stream is guided by a flap valve assembly having at least one flap valve which, with regard to good regulation of temperature with low energy consumption, is configured and developed in such a way that the flap valve assembly comprises at least three flap valves, which can be controlled as a function of a parameter, in particular as a function of an environmental parameter. The invention further relates to a system for regulating temperature and to a method for operating such a system.

This application is a 371 national application based on PCT international application PCT/EP2010/002552 (international publication number WO 2010/124830 A1), filed Apr. 26, 2010, and claims priority from that application, and also from European application 09005824.9, filed Apr. 27, 2009. The contents of both applications are incorporated herein in their entirety.

### BACKGROUND OF THE INVENTION

The present invention relates to a mixing box for regulating temperature, that has a base body through which at least one air current can be conducted and in which at least one filter arrangement is arranged through which the air current can be conducted, whereby the guidance of the air current takes place by a flap arrangement with at least one flap. The invention furthermore relates to a system for regulating temperature as well as to a method for operating such a system.

Mixing boxes for temperature regulation are known from the state of the art. Furthermore, systems for temperature regulation from the state of the art are known for various applications. One application possibility for such systems is the air conditioning of individual rooms or of entire buildings. Systems for the regulation of temperature are required in particular for the air conditioning of computer centers since a significant development of heat takes place by the operation of computer systems, for example, server systems. The heat produced by the server systems must necessarily be removed from the room in which the server systems stand because the maximal operating temperatures for such server systems are in the area of 35° C., which is reached and exceeded in a short time without removal of the heat produced by the servers.

DE 199 04 667 teaches a system for the temperature regulation of a building. The system shown in it comprises an air-conditioning apparatus that comprises a cooling-agent circuit that makes possible an indirect cooling of the building or of individual rooms by means of the cooling agent. Such a cooling is in particular advantageous by virtue of the fact that the admissible area of the relative air moisture and the desired temperature can be very well maintained. The cooling of the system shown takes place as a function of the outside temperature either as indirect free cooling in the winter, as active cooling in the summer as well as indirect free in combination with an active cooling in the transitional time. However, such a cooling is very cost-intensive on account of the high energy requirement of an indirect cooling.

### SUMMARY OF THE INVENTION

The present invention therefore addresses the problem of making available a mixing box for temperature regulation that makes possible a good temperature regulation with low energy consumption. A further problem addressed by the invention is to make available a system for the regulation of temperature as well as a method for operating a system for temperature regulation.

According to the invention provision is made for solving the problem in a mixing box of the initially cited type in that the flap arrangement comprises at least three flaps that can be controlled as a function of a parameter, in particular as a function of an ambient parameter.

The use of three flaps makes many different operating states of the mixing box possible, as a result of which the mixing box can be adjusted in a much more individual manner to different operating states and requirements. Thus, it is possible to lower the energy requirement since an individual adjustment can be carried out for individual operating points so that the operating state can be selected that has a minimal energy requirement in this operating point. A preferred ambient parameter is the temperature, for example, the outside temperature. In addition or alternatively even other ambient parameters are conceivable such as the particle load of the air or the air moisture as parameters on which the control of the flap arrangement depends.

Advantageous further developments and embodiments of the invention are apparent from the description herein.

### BRIEF DESCRIPTION OF THE FIGURES

FIG. 1 shows a schematic view of the mixing box in accordance with the invention.

FIG. 2 shows a schematic view of a system in accordance with the invention for regulating the temperature in a first operating state.

FIG. 3 shows a schematic view of a system in accordance with the invention for regulating the temperature in a second operating state.

FIG. 4 shows a schematic view of a system in accordance with the invention for regulating the temperature in a third operating state.

FIG. 5 shows a schematic view of a system in accordance with the invention for regulating the temperature in a fourth operating state.

FIG. 6 shows a schematic view of a system in accordance with the invention for regulating the temperature in a fifth operating state.

### DESCRIPTION OF THE INVENTION

In an advantageous embodiment two filter apparatuses could be provided through which the air current can be conducted. A filter apparatus could comprise a single filter type or a filter combination, for example, two, three or more filter types through which the air current sequentially flows. In a preferred embodiment one of the filter apparatuses could comprise a filter of filter class G4 and the other filter apparatus could comprise a combination of two filters of filter classes G4 and F7. An air current from outside the building in which the computer center is located could then pass through the combination of G4 and F7 filters so that at first rough purification takes place by the G4 filter and then fine particles are filtered out of the air current by the F7 filter. In an air current that passes out of the computer center into the mixing box the filtering of fine particles by an F7 filter is sufficient since this air has already been purified.

In the framework of a further advantageous embodiment the flap arrangement could be shaped in such a manner and/or controlled as a function of the parameter in such a manner that the air current passes through one or both filter apparatuses. If the air current passes only through one filter apparatus, this means that either a 100% exchange of air takes place between the area to be tempered and the outside area, or that a recirculated-air operation takes place. In particular in those instances in which the air current passes through a filter apparatus that only has one filter type, the pressure drop is usually distinctly less than when the air current has to pass through a filter combination. This leads again to a savings of energy since further on, for example, in a ventilator, the pressure does not have to be built up again. If air currents pass both filter apparatuses, this is a mixed operation in which a change of air with the outside air as well as a recirculation of the air inside the area to be cooled takes place. The control of the flap arrangement could take place in an especially simple manner by a microcontroller.

In the framework of an especially simple embodiment the flap arrangement could comprise a flap for outside air and/or an air recirculation flap and/or a mixed-air flap.

In order to improve the regulation of temperature the base body could be associated with a compressor in certain operating states, for example, at temperatures of the incoming air, also called outside air, above 17° C. Above 25° C. an active cooling by the compressor could take place while in the range above 17° C. and below 25° C. only a mixed operation of active and direct cooling could take place, as a result of which the energy costs could be lowered again. Below 17° C. a direct free cooling is possible so that the energy requirement can be distinctly lowered and nevertheless the boundary values of the ASHRAE TC 9.9—2008 guideline can be maintained. A high energy efficiency can be ensured by using the free cooling since no energy losses, for example, by additional heat exchangers, occur. The compressor could be integrated here in the base body as well as arranged as a separate structural component on the base body. However, the system could basically be water-cooled or air-cooled.

According to another aspect of the present invention a system for temperature regulation is suggested in which several mixing boxes are provided that are arranged parallel to each other. Since no hydraulic design such as piping, pumps or fittings are required in the system of the invention, a very good scalability of the system is given so that it can be expanded or reduced at any time with simple means according to the requirement. Moreover, the invention costs are therefore less in comparison to known systems with indirect free cooling.

In a further advantageous embodiment at least one ventilator apparatus could be provided. This ventilator apparatus could be present outside of the area to be cooled, for example, outdoors, in order to improve the removal of the warm air. In particular at outdoor temperatures above 17° C. such an additional removal of heat could take place by the ventilator apparatus.

Furthermore, the invention relates to a method of such a system for regulating the temperature in which the flap arrangement is controlled in such a manner that the air current passes through one or both filter arrangements as a function of a parameter, in particular as a function of the temperature. An appropriate software could be advantageously used to control the flap arrangement. A high energy efficiency can be ensured by the method in accordance with the invention since no energy losses, for example, by additional heat exchangers, occur.

The invention is described in the following using an exemplary embodiment that is schematically shown in the drawings described here.

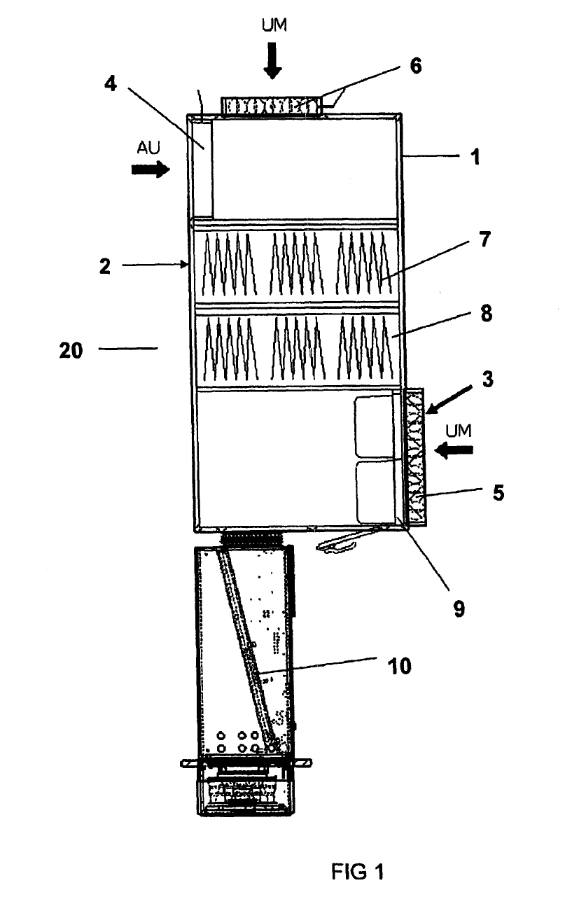

FIG. 1 schematically shows an exemplary embodiment of a mixing box 20 in accordance with the invention. The mixing box 20 has a base body 1 that comprises a flap arrangement and two filter apparatuses 2, 3, whereby the flap arrangement comprises an outside air flap 4, a recirculated air flap 5 and a mixed air flap 6. Filter apparatus 2 comprises a G4 filter 7 that is arranged in the direction of flow of the air currents passing through the filter apparatus 2 in front of an F7 filter 8. Outside air AU as well as, if a filter preheating takes place, pre-warmed air UM1 passes through the filter apparatus 2 if the appropriate outside air flap 4 and optionally the mixed air flap 6 are open. The second filter apparatus 3 comprises a G4 filter 9 through which an air current UM2 passes in the operating states in which a recirculated air operation takes place. The air current UM2 circulates in this operating state inside the room to be cooled, that is a computer center in this exemplary embodiment. In addition, a separate structural component is built onto the base body 1 of the mixing box 20 in which component a compressor 10 is arranged in such a manner that the basic body 1 and the structural component are in a flow connection.

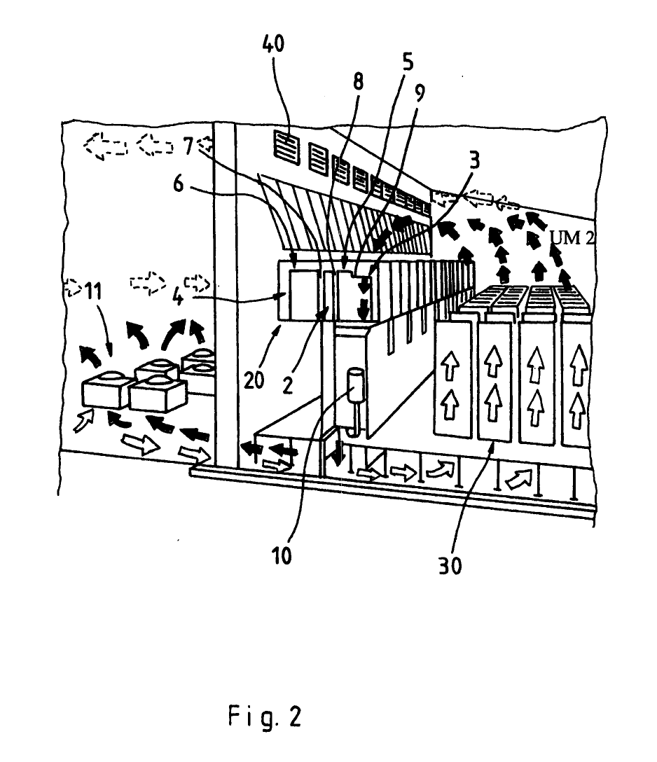

The method of operation of mixing box 20 in a system that is also in accordance with the invention is shown in FIG. 2 to 6, which show five different operating states of the system for regulating the temperature of a computer center. The computer center comprises a plurality of servers 30 that produce heat during operation. Furthermore, ventilation flaps 40 for the free exchange of air between the room air of the computer center and outside air of the environment outside of the building in which the computer center is located are located in the outer wall of the computer center. The air temperature of the room inside the computer center should be regulated in this exemplary embodiment to 27° C.

FIG. 2 shows a system in accordance with the invention for regulating the temperature of the computer center in a first operating state. This operating state is at an outside temperature that is equal to or greater than 25° C. At such a high outside temperature the system for temperature regulation is operated in the so-called recirculated air- and compressor operation. Since the compressor 10 is in operation, this means that an active cooling of the computer center takes place. The solid arrows symbolize here warm air currents whereas the arrows that are not solid symbolize cool air currents. In this operating state the outside air flap 4 as well as the mixed air flap 6 are closed and the recirculated air flap 5 is open. Accordingly, an air current UM2 circulates from the servers 30 into the mixing box 20, passes through the F7 filter 9 and is removed via ventilator apparatuses 11 into the environment. A slight exchange of air between the room air and the outside air is possible conditioned by the temperature gradient as a function of the temperature gradient between the temperature of the room air in the computer center and the outside temperature. These slight air currents are represented by dotted arrows.

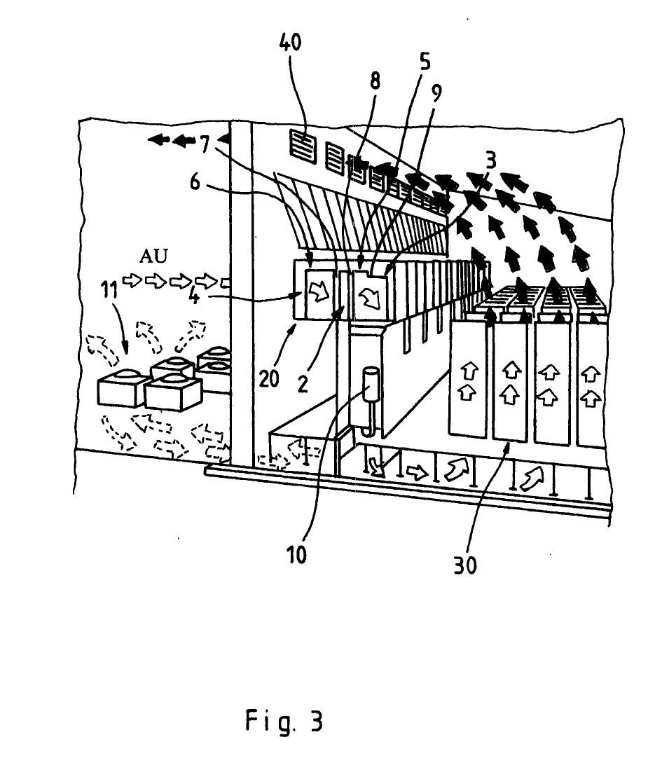

FIG. 3 shows the system of the invention for temperature regulation in a second operating state that is present at an outside temperature above 17° C. and below 25° C. In this operating state a 100% exchange of air takes place inside the computer center, for which reason the outside air flap 4 is open and the recirculated air flap 5 and the mixed air flap 6 are closed. The air current AU accordingly passes through the G4 filter 7 and the F7 filter 8 of the filter apparatus 2 into the mixing box 20 and exits from the computer center via the ventilation flaps 40. For a sufficient cooling of the computer center the compressor 11 is operated in addition to the direct cooling by the air exchange, by means of which compressor an active cooling of the computer center additionally takes place. Furthermore, a lesser current of warm air is removed by the ventilator apparatuses 11.

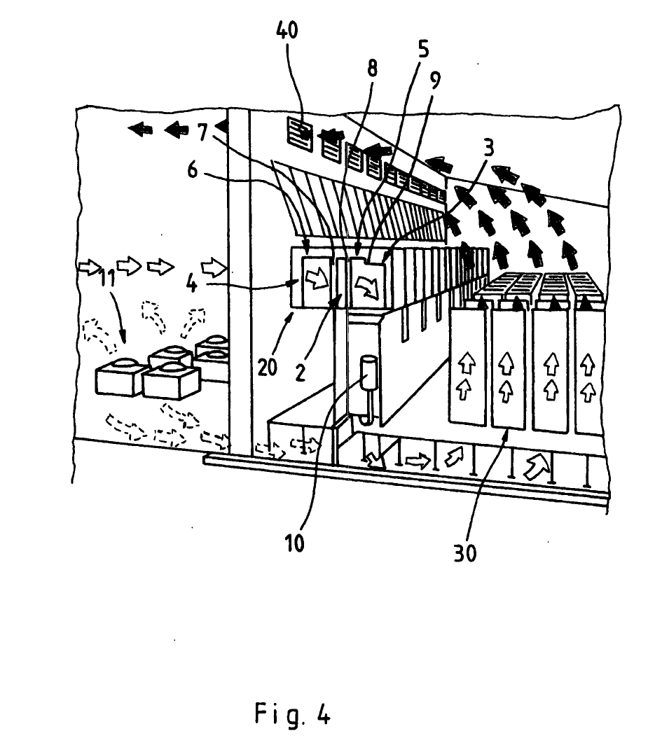

A third operating state of the system of the invention for temperature regulation is shown in FIG. 4. This operating state, in which a direct free cooling takes place only by a 100% exchange of air is possible at an outside temperature of 17° C. Accordingly, the air current AU passes through the G4 filter 7 and the F7 filter 8 of the filter apparatus 2 into the mixing box 20 and exits out of the computer center via the ventilation flaps 40. An operation of compressor 10 or of ventilator apparatuses 11 does not take place in this operating state.

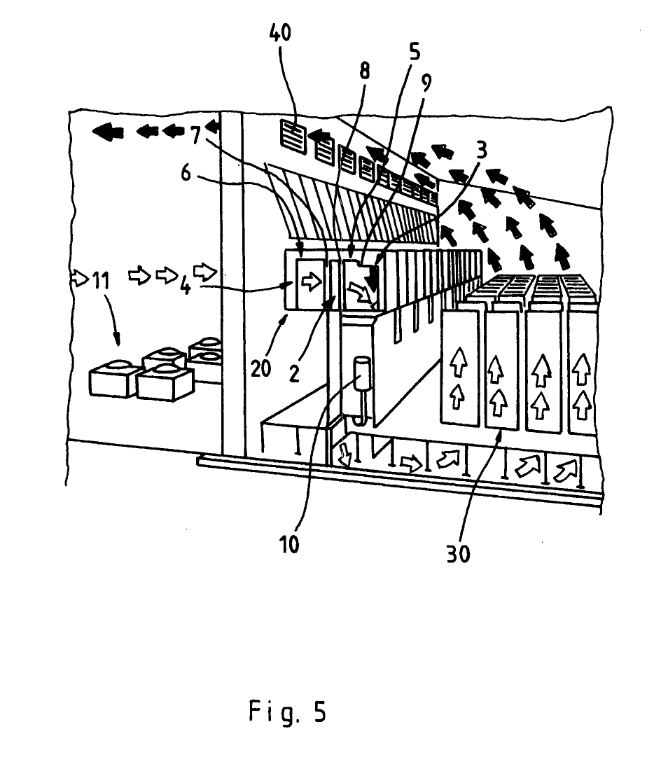

The system in accordance with the invention for temperature regulation can be operated in a fourth operating state in a mixed operation with recirculated air. This operating state is shown in FIG. 5. In the exemplary embodiment described here this operating state is adjusted at an outside temperature of 0° C. to below 17° C. In this operating state, which is shown in detail in FIG. 5, the outside air flap 4 and the mixed air flap 6 are open while the recirculated air flap 5 is closed.

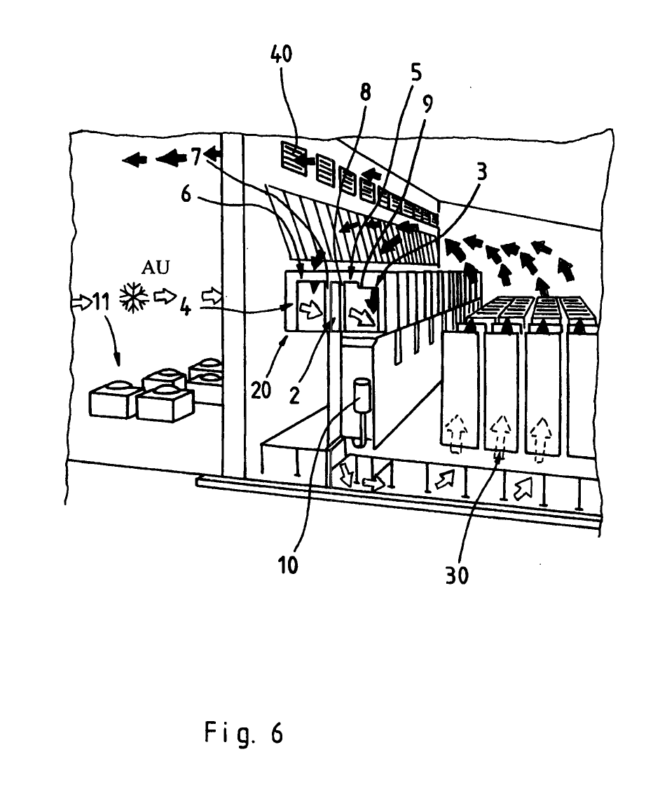

If the outside temperature is lower than 0° C. the system for temperature regulation is operated in a fifth operating state, as is shown in FIG. 6. This operating state is also a mixed operation with recirculated air and filter pre-heating. Here, the outside air AU entering through the outside air flap 4 from the environment into the mixing box 20 is pre-heated by the room air heated by the servers 30 which room air enters through the mixed air flap 6 into mixing box 20. Accordingly, the outside air flap 4 and the mixed air flap 6 are open while the recirculated air flap 5 is closed. Furthermore, warm air exits through the ventilation flaps 40 into the environment. Accordingly, an especially energy-efficient direct, free cooling of the computer center takes place in the operating state shown in FIGS. 5 and 6.

1. A mixing box for regulating temperature, that has a base body through which at least one air current can be conducted and in which at least one filter arrangement is arranged through which the air current can be conducted, whereby the guidance of the air current takes place by a flap arrangement with at least one flap, characterized in that the flap arrangement comprises at least three flaps that can be controlled as a function of a parameter.

2. The mixing box for temperature regulation according to claim 1, wherein the three flaps are controlled as a function of a parameter of the environment.

3. The mixing box for temperature regulation according to claim 1, wherein the air current is conducted through two filter apparatuses.

4. The mixing box for temperature regulation according to claim 3, wherein the flap arrangement is shaped in such a manner and/or can be controlled in such a manner as a function of the parameter that the air current passes only through one filter apparatus.

5. The mixing box for temperature regulation according to claim 1, wherein the flap arrangement comprises an outside air flap and/or a recirculated air flap and/or a mixed air flap.

6. The mixing box for temperature regulation according to claim 1, wherein a compressor unit is associated with the base body.

7. The mixing box for temperature regulation according to claim 1, wherein the flaps can be controlled as a function of the temperature.

8. The mixing box for temperature regulation according to claim 7, wherein the flaps can be controlled as a function of the outside air temperature or the supply air temperature.

9. A method for temperature regulation with a mixing box, which mixing box has a base body through which at least one air current can be conducted and in which at least one filter arrangement is arranged through which the air current can be conducted, whereby the guidance of the air current takes place by a flap arrangement with at least one flap, characterized in that the flap arrangement comprises at least three flaps that can be controlled as a function of a parameter,
comprising the steps of
allowing at least one air current to be conducted through the base body and through the at least one filter arrangement,
guiding the air current by the flap arrangement, which flap arrangement is controllable as a function of the particle load of the air or of the air moisture.

10. A system for temperature regulation, comprising two of more mixing boxes arranged parallel to each other, wherein each mixing box has a base body through which at least one air current can be conducted and in which at least one filter arrangement is arranged through which the air current can be conducted, whereby the guidance of the air current takes place by a flap arrangement with at least one flap, wherein the flap arrangement comprises at least three flaps that can be controlled as a function of a parameter.

11. The system for temperature regulation according to claim 10, which further comprises ventilator apparatuses.

12. A method for operating a system for temperature regulation, which system comprises two of more mixing boxes arranged parallel to each other, wherein each mixing box has a base body through which at least one air current can be conducted and in which at least one filter arrangement is arranged through which the air current can be conducted, whereby the guidance of the air current takes place by a flap arrangement with at least one flap, wherein the flap arrangement comprises at least three flaps that can be controlled as a function of a parameter,
comprising the steps of
allowing at least one air current to be conducted through the base body and through the at least one filter arrangement of each of the mixing boxes,
guiding the air current by the flap arrangement, which flap arrangement is controllable such that the air current passes through one of the filter arrangements as a function of a parameter.

13. The method according to claim 12, wherein the flaps can be controlled as a function of the temperature.

14. The method according to claim 12, wherein the three flaps include characterized in that a first operating state, an outside air flap and a mixed air flap, and wherein
a. in a first operating state the outside air flap and the mixed air flap are closed and the recirculated air flap is open,
b. in a second operating state the outside air flap is open and the recirculated air flap and the mixed air flap are closed,
c. in a third operating state the outside air flap is open and the mixed air flap and the recirculated air flap are closed,
d. in a fourth operating state the outside air flap and the mixed air flap are open and the recirculated air flap is closed, and
e. in a fifth operating state the outside air flap and the mixed air flap are open and the recirculated air flap is closed.
